(19) United States
(12) Patent Application Publication
(10) Pub. No.: US 2024/0381566 A1
(43) Pub. Date: Nov. 14, 2024

(54) COOLING PLATE

(71) Applicant: Robert Bosch GmbH, Stuttgart (DE)

(72) Inventor: Klaus Ries-Mueller, Bad Rappenau (DE)

(21) Appl. No.: 18/687,001

(22) PCT Filed: Jul. 29, 2022
(86) PCT No.: PCT/EP2022/071341

§ 371 Date: Feb. 27, 2024

(30) Foreign Application Priority Data
Aug. 30, 2021 (DE) 10 2021 209 503.8

(51) Int. Cl. H05K 7/20

(52) U.S. Cl. CPC H05K 7/20254; H05K 7/20927

(57) ABSTRACT

The present invention relates to a cooling plate (1) of a cooler (10), through which fluid can flow, for cooling power electronics (200). The cooling plate (1) comprises a main body (2) and a plurality of cooling fins (3), which protrude from the main body (2). A surface (20) of the main body (2) and/or surface (30) of at least one cooling fin (3) has at least one defined microstructured region (4). Another aspect of the invention relates to a cooler (10) of this type and to a power electronics assembly (100).

### BACKGROUND

The present invention relates to a cooling plate of a cooler, through which fluid can flow, for cooling power electronics with an improved cooling effect. The invention also relates to a cooler through which fluid can flow and which has such a cooling plate, as well as to a power electronics assembly comprising power electronics and a cooler.

Cooling plates, which are used to cool power electronics units, are known from the prior art in various designs. In order to dissipate heat generated by a power electronics unit, the power electronics unit is usually attached to the cooling plate in such a way that the heat is first transferred to the cooling plate and then from it to a cooling medium. For this purpose, the cooling plate usually has an enlarged surface area on the side facing the flow of the cooling medium, which is provided with ribs.

### SUMMARY

The cooling plate of a cooler through which fluid can flow for cooling power electronics according to the invention has the advantage of an improved cooling effect. In particular, the conflict of objectives between the low cost of a cooling plate and maximum cooling effect with minimum size can be resolved. The cooling fin according to the invention is therefore particularly suitable for use in coolers through which fluid can flow for high-performance electronic applications. These advantages are achieved by micro-structuring the surface of the cooling plate. In particular, the cooling plate of a cooler through which fluid can flow for cooling power electronics comprises a main body and a plurality of cooling fins which protrude from the main body. A surface of the main body and/or a surface of at least one cooling fin has/have at least one defined (predefined) microstructured region. The microstructured region of the surface, also referred to as the surface region in the context of the present invention, leads on the one hand to an enlargement of the surface area of the cooling plate and thus also to contact of the cooling plate with a cooling medium which flows through cooling channels formed between the cooling fins and through which the heat of the power electronics can be dissipated. On the other hand, the microstructured region leads to a change in the flow properties of the cooling medium and, in particular, to the generation or amplification of turbulence, which results in an increase in cooling efficiency. In contrast to a laminar flow, which only transfers heat by conduction, a turbulent flow transports heat by both conduction and convection, which significantly increases cooling efficiency. By optimally cooling the power electronics, the temperature of a power electronics unit, such as an inverter for an electric vehicle drive, can be kept as low as possible, allowing the highest possible power densities to be realized. It should be noted that the term “defined microstructured region” means in particular that a region of a surface of the main body and/or a surface of at least one cooling fin is/are specifically surface-machined so that the region has a defined microstructure. The defined (predefined) microstructured region is in particular a region that has a defined (predefined) shape and/or defined (predefined) size. The predetermined microstructuring of the surface of the main body or of the at least one cooling fin is not to be confused with a potential roughness of the corresponding surface, which is produced by a manufacturing process of the cooling plate. This means that the present invention specifically provides for microstructuring of the surface so that an improved cooling effect is achieved. Advantageously, only part of the entire surface of the cooling plate is microstructured. The remainder of the entire surface of the cooling plate is then not microstructured within the meaning of the present invention, since it does not comprise a defined microstructured region or defined microstructured regions. The term “micro-” means in particular that at least one dimension of the microstructured region is in the μm range, in particular between 4 μm and 300 μm, preferably between 10 μm and 100 μm. It should also be noted that the at least one cooling fin can have any shape. The cooling fin can therefore be plate-shaped or pin-shaped, for example. In the context of the invention, the cooling plate can advantageously also be referred to as a heat conducting plate, as it can conduct heat generated by the power electronics.

Preferably, the microstructured region of the surface of the main body is formed by at least one indentation. In particular, the indentation can increase the contact area and the flow path for the cooling medium. The indentation can preferably be designed as a trough, i.e., in particular that the indentation is preferably curved or has a curved surface area/shape.

Preferably, the microstructured region of the surface of the main body is formed on a cooling fin. The microstructured region of the surface of the main body is preferably formed directly on a cooling fin. The microstructured region merges directly into the cooling fin, in particular a wall of the cooling fin. In particular, this means that the microstructured region corresponds to a transition region between the main body and a cooling fin. This arrangement of the microstructured region relative to the cooling fin increases the generation of turbulence by the flow of the cooling medium on the cooling fin. In particular, the at least one indentation is formed, preferably directly, on the cooling fin. If the microstructured region has a plurality of indentations, the microstructured region is positioned relative to a cooling fin in such a way that one indentation of the plurality of indentations is formed, preferably directly, on the cooling fin.

Preferably, the microstructured region of the surface of the main body is arranged in a flow direction of a coolant upstream of a cooling fin, i.e., in front of a cooling fin. It should be understood that this relates in particular to the situation in which the cooling plate is in its intended operating position. This allows part of the cooling medium to reach the microstructured region first and then the corresponding cooling fin.

A width of the microstructured region of the surface of the main body preferably corresponds to a width of the cooling fin to which the microstructured region of the surface of the main body is assigned. The width of the microstructured region/the at least one cooling fin corresponds to the corresponding dimension of the microstructured region/the at least one cooling fin in the flow direction of the cooling medium, in particular in the intended operating position of the cooling fin.

Preferably, the at least one microstructured region of the surface of the main body comprises a plurality of microstructured regions. In other words, the surface of the main body comprises a plurality of microstructured regions.

A microstructured region of the surface of the main body is particularly preferred for each cooling fin.

Advantageously, only part of the entire surface of the main body is microstructured. Preferably a maximum of 50%, particularly preferably a maximum of 30%, of the entire surface of the main body is microstructured. This means that the plurality of microstructured regions has a total area content which corresponds to a maximum of 50%, particularly preferably a maximum of 30%, of the total area content of the surface of the main body. Area content of each microstructured region is the area content of a surface area that results when the corresponding microstructured region is projected onto the plane of the surface of the main body.

Preferably, the microstructured region of the at least one cooling fin is formed by at least one indentation. As with the indentation in the microstructured region of the main body, the indentation on the cooling fin also increases the contact area and flow path for the cooling medium. The indentation can preferably be curved. In other words, the microstructured region can preferably have a curved surface area/shape at the location of the indentation.

Preferably, the surface of the at least one cooling fin is the surface of a peripheral area of the cooling fin. The microstructured region of the cooling fin extends in an advantageous manner in a peripheral direction over a complete periphery of the cooling fin or a part of it. Preferably, the microstructured region extends over the entire height of the cooling fin or part of it.

The microstructured region of the surface of the main body can preferably comprise a plurality of indentations arranged in such a way that the microstructured region has a corrugated shape.

Similarly, the microstructured region of the surface of the at least one cooling fin can preferably comprise a plurality of indentations arranged in such a way that the microstructured region has a corrugated shape.

Preferably, the microstructured region of the main body and/or the at least one cooling fin can have a corrugated shape comprising a plurality of indentations. It should be understood that the corrugated shape is advantageously formed by the plurality of indentations and additionally at least one ridge in particular a plurality of ridges. If the microstructured region is formed on the at least one cooling fin and extends completely in a peripheral direction, the microstructured region can advantageously be threaded.

A depth, in particular a maximum depth, of each indentation is preferably between 4 μm and 300 μm, particularly preferably between 10 μm and 100 μm.

Preferably, the cooling plate can be designed as a pin-fin plate. The cooling fins are pin-shaped. In other words, the cooling fins are designed as pins. In particular, the pins can each be shaped as a circular cylinder, cone or cuboid. In the pin-fin plate, the pins are advantageously arranged in such a way that the pins form parallel and vertical rows in the form of a grid. This arrangement of the cooling fins formed as pins enables increased turbulence effects in the flow of the cooling medium. The cooling fins of the pin fin plate, together with the at least one microstructured region, result in an even greater enlargement of the actual surface area used to dissipate the heat generated by the power electronics.

In the context of the invention, the plurality of cooling fins can also be referred to in particular as a pin-fin structure.

In an advantageous manner, the at least one microstructured region of the surface of the main body and/or the surface of the at least one cooling fin is produced by surface treatment of the corresponding surface, in particular by means of a laser.

The cooling plate can preferably be manufactured using a forming process.

The cooling plate is preferably made of a material that has a thermal conductivity coefficient greater than 200 W/(m-K).

The cooling plate is advantageously made of metal. In particular, aluminum can be used, which is inexpensive and lightweight. On the other hand, aluminum has a high coefficient of thermal conductivity and is relatively easy to process. This means that the surface of the cooling plate can also be microstructured without great effort.

Preferably, the surface of the main body can have a plurality of defined microstructured regions.

Preferably, the microstructured regions of the main body are each assigned to a cooling fin.

Preferably, the microstructured regions of the main body can be designed in such a way that an enlargement of the surface area of the main body caused by the microstructured regions increases in a direction in which the cooling fins are arranged. In other words, this means that a surface area of the microstructured regions or their area content preferably increases in the direction of arrangement.

Furthermore, the microstructured regions of the main body can preferably each be formed by an indentation. The indentations are formed in such a way that the maximum depth of the indentations increases in the direction of arrangement. This means that the flow properties of the cooling medium can be influenced in the direction of arrangement. In particular, stronger turbulence effects can be caused by an indentation with a greater depth than by an indentation with a smaller depth.

Preferably, the surface of each cooling fin of the plurality of cooling fins can have a defined microstructured region.

The microstructured regions of the cooling fins are preferably designed in such a way that an enlargement of the surface area of the cooling fins caused by the microstructured regions increases in the direction of arrangement. In other words, this means that a surface area of the microstructured regions or their area content preferably increases in the direction of arrangement.

Preferably, the distance from the center of the indentation to the center of the indentation of the microstructured regions of the cooling fins can decrease in the direction of arrangement. This allows the surface area of the cooling fins to be enlarged in the direction of arrangement. Preferably, the height of the indentations of different microstructured regions can be the same. For cooling fins of the same height, a distance from the center of the indentation to the center of the indentation of a microstructured region of a first cooling fin that is greater than the corresponding distance of a microstructured region of a second cooling fin means, in particular, that the first cooling fin has a smaller number of indentations than the second cooling fin.

The direction in which the cooling fins are arranged is advantageously parallel to the flow direction of a cooling medium.

The present invention also relates to a cooler through which fluid can flow for cooling power electronics. The cooler through which fluid can flow comprises a cooling plate as described above and an interior in which the cooling fins of the cooling plate are arranged. The main body of the cooling plate can preferably form part of the housing of the radiator. The housing can also comprise a housing part. The interior of the cooler is advantageously formed/defined by the housing.

The cooling medium is advantageously a fluid, in particular cooling water.

The present invention further relates to a power electronics assembly comprising power electronics and a cooler as described above.

Preferably, the power electronics comprise a plurality of power electronics units that are arranged one after the other in a flow direction of a cooling medium.

In particular, the power electronics can comprise a first power electronics unit and a second power electronics unit. The power electronics units are arranged in such a way that the first power electronics unit is cooled first and then the second power electronics unit is cooled by the cooling medium. Furthermore, the power electronics can preferably comprise a third power electronics unit which is arranged downstream of the second power electronics unit, i.e., downstream of the second power electronics unit, in the flow direction of a cooling medium. The third power electronics unit is the last to be cooled.

Further preferably, the at least one predefined microstructured region can comprise a plurality of predefined microstructured regions which are designed in such a way that all power electronics units experience the same cooling capacity.

In particular, the power electronics can be an inverter for an electric vehicle drive, especially an electric motor of an electric vehicle. The inverter is set up to convert a DC voltage from the battery into AC voltage for the electric vehicle drive. The first power electronics unit, the second power electronics unit and the third power electronics unit each comprise a half-bridge. The three half bridges form a B6 bridge and are used to control the three phases (phase U, phase V and phase W).

It should be noted that in the context of the invention, the power electronics unit can also be referred to as a power module.

It should also be noted that in the context of the invention, the flow direction of the cooling medium corresponds in particular to a main flow direction of the cooling medium. In particular, the main flow direction is the direction in which the cooling medium mainly flows, i.e., the direction in which a velocity component of the cooling medium is greater than a velocity component of the cooling medium in a secondary flow direction that is perpendicular to the main flow direction. The main flow direction preferably corresponds to the direction in which the cooling medium is introduced into a cooler through which fluid can flow.

### BRIEF DESCRIPTION OF THE DRAWINGS

In the following, exemplary embodiments of the invention are described in detail with reference to the accompanying drawing, wherein identical or functionally identical components are each designated by the same reference sign. The following is shown in the drawings:

FIG. 1 a simplified schematic sectional view of a part of a cooling plate according to a first exemplary embodiment of the present invention,

FIG. 2 a simplified schematic sectional view of a part of the cooling plate from FIG. 1,

FIG. 3 a simplified schematic sectional view of a power electronics assembly according to the invention with a cooler according to the first exemplary embodiment, which comprises the cooling plate from FIG. 1,

FIG. 4 a simplified schematic sectional view of a part of a cooling plate according to a second exemplary embodiment of the present invention,

FIG. 5 a simplified schematic sectional view of a part of the cooling plate from FIG. 4,

FIG. 6 a simplified schematic sectional view of a part of a cooling plate according to a third exemplary embodiment of the present invention, and

FIG. 7 a simplified schematic sectional view of a part of a cooling plate according to a fourth exemplary embodiment of the present invention.

### DETAILED DESCRIPTION

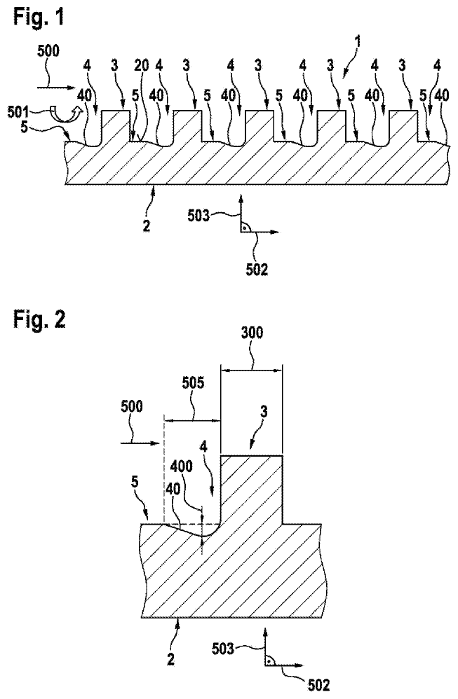

With reference to FIGS. 1 through 3, a cooling plate 1, a cooler 10 through which fluid can flow, which has the cooling plate 1, and a power electronics assembly 100, which has the cooler 10 and power electronics 200, are described in detail below in accordance with a first exemplary embodiment of the invention.

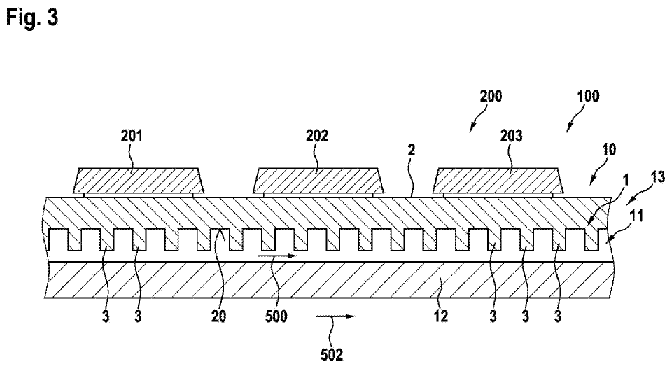

FIGS. 1 and 2 each show a region of the cooling plate 1, while FIG. 3 shows the power electronics assembly 100 with the cooler 10 through which fluid can flow.

The cooling plate 1 comprises a main body 2 and a plurality of cooling fins 3 which protrude from the main body 2.

The cooler 10, through which fluid can flow, with the cooling plate 1 is used to cool the power electronics 200, which according to FIG. 3 has a first power electronics unit 201, a second power electronics unit 202 and a third power electronics unit 203.

In particular, the power electronics 200 can be an inverter for an electric vehicle drive, in particular an electric motor of an electric vehicle. The inverter is set up to convert the DC voltage of the battery into AC voltage for the electric vehicle drive. Here, the first power electronics unit 201, the second power electronics unit 202 and the third power electronics unit 203 each comprise a half-bridge. The three half bridges form a B6 bridge and are used to control the three phases (phase U, phase V and phase W). However, the power electronics 200 can also be provided in other applications.

As can also be seen from FIG. 3, the first power electronics unit 201, the second power electronics unit 202 and the third power electronics unit 203 are mounted on the cooling plate 1, in particular on a side of the main body 2 of the cooling plate 1 facing away from the cooling fins 3, for the purpose of cooling the power electronics 200.

In this exemplary embodiment, the cooling plate 1 is part of a housing 13, which also comprises a housing part 12. The housing part 12, which is designed in particular as a plate, defines an interior 11 together with the cooling plate 1. The cooling plate 1 is arranged relative to the housing part 12 in such a way that the cooling fins 3 are located in the interior 11. A cooling medium, in particular cooling water, flows through the interior 11, in particular through cooling channels formed between the cooling fins 3, in a flow direction 500. This means that heat generated by the power electronics units 201 through 203 during operation can be transferred to the cooling medium via the cooling plate 1, in particular the cooling fins 3, and dissipated.

In an advantageous way, the cooling plate 1 is designed as a pin-fin plate. The cooling fins 3 are pin-shaped, i.e., in the form of pins, and positioned on the main body in such a way that they form parallel and vertical rows in the form of a grid. In particular, all cooling fins 3 are identical. This arrangement of the cooling fins 3 enables increased turbulence effects in the flow of the cooling medium. However, a different design of the cooling fins 3 and/or a different arrangement of the cooling fins 3 on the main body 2 is also possible. It is also possible for the cooling fins 3 to differ from one another in terms of their shape and/or dimensions.

One surface 20 of the main body 2 is microstructured to increase the turbulence effects of the flow of the cooling medium and to enlarge the surface area through which heat can be dissipated. The surface 20 of the main body 2 can be advantageously microstructured by means of laser surface treatment. The surface 20 corresponds to the surface of the side face of the main body 2, from which the cooling fins 3 protrude.

FIGS. 1 and 2 also show that the surface 20 of the main body 2 has a plurality of defined (predefined) microstructured regions 4. It should be noted that the surface 20 of the main body 2 is shown in FIG. 3 without the microstructured regions 4 for reasons of representation.

All microstructured regions 4 are formed as curved indentation 40, each of which has a maximum depth 400 according to FIG. 2. In particular, the indentations 40 are shaped as troughs.

Advantageously, the indentations 40 are each formed in such a way that they have their maximum depth 400 at a point which is closer to a first end of the respective indentation 40 than to a second end of the indentation 40. In this case the first end faces a cooling fin 3 compared to the second end.

In particular, all indentations 40 are identically formed. This means that all indentations 40 have the same shape and maximum depth 400. This simplifies the surface treatment of the surface 20. The depth 400 of an indentation 40 is a dimension parallel to a direction 503, which is perpendicular to a direction of arrangement 502 of the cooling fins 3 or perpendicular to the surface 20. The direction of arrangement 502 is parallel to the flow direction 500.

As can also be seen from FIGS. 1 and 2, each indentation 40 is associated with a cooling fin 3. This means that the number of microstructured regions 4 or indentations 40 is equal to the number of cooling fins 3. Advantageously, only part of the entire surface of the main body is microstructured. Preferably, a maximum of 50%, particularly preferably a maximum of 30%, of the entire surface 20 of the main body 20 is microstructured.

In particular, each indentation 40 is formed directly on a cooling fin 3 and is arranged upstream of the corresponding cooling fin 3 in the flow direction 500 of the coolant. Here, each indentation 40 or the first end of each indentation 40 merges into the corresponding cooling fin 3. A width 505 of the indentations 40, which is drawn with reference to the cooling fin 3 shown in FIG. 2, corresponds to a width 300 of the cooling fins 3. The width 300 of the cooling fins 3 and the width 505 of the indentations 40 correspond to the respective dimension in the flow direction 500 of the cooling medium.

The indentations 40 can cause high turbulence, indicated by the arrow 501 in FIG. 1, in the flow of the cooling medium, which leads to higher heat dissipation. The enlargement of the overall surface area of the cooling plate 1 due to the microstructured regions 4 of the surface 20 also contributes to better heat transfer, as this increases the contact between the main body 2 and the flowing cooling medium.

Furthermore, it can be seen from FIGS. 1 and 2 that the surface 20 of the main body 2 has a plurality of regions 5 which are not microstructured—in the sense of the present invention—and which, together with the predefined microstructured regions 4, form the surface 20 of the main body 2.

The cooling plate 1 according to the invention can meet the requirements of power electronics units with the highest possible power density, such as the power electronics units 201 through 203, due to its previously described design. In particular, the cooling plate 1 can be made of aluminum, so that weight can be saved and optimum corrosion protection against the cooling medium can be achieved. The production costs of the cooling plate 1 can be reduced remotely.

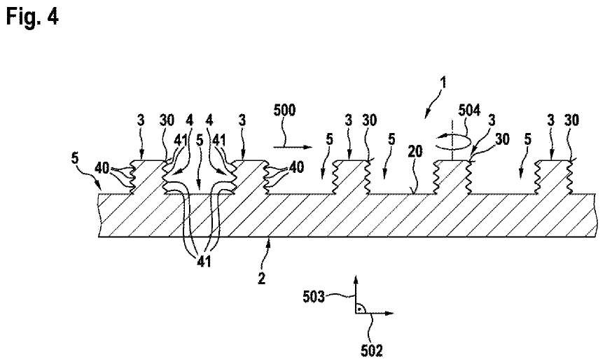

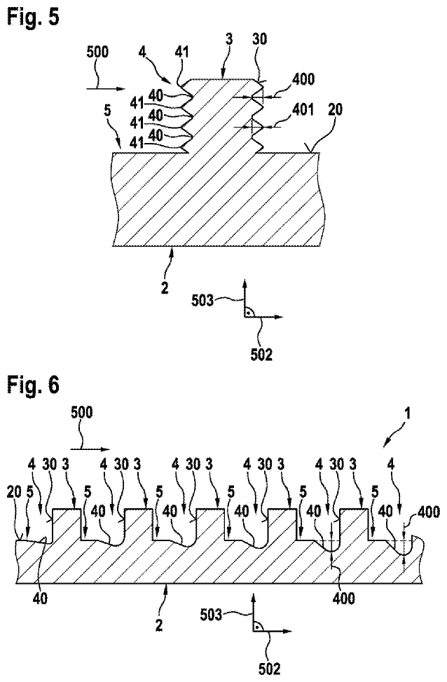

FIGS. 4 and 5 relate to a cooling plate 1 according to a second exemplary embodiment of the present invention. The cooling plate 1 according to the second exemplary embodiment can replace the cooling plate 1 according to the first exemplary embodiment in the power electronics assembly 100 shown in FIG. 3.

The cooling plate 1 according to the second exemplary embodiment differs from that according to the first exemplary embodiment in that instead of the surface 20 of the main body 2, the surfaces 30 of the cooling fins 3 are microstructured. In particular, the surfaces 30 are corresponding surfaces of the peripheral areas of the cooling fins 3. All cooling fins 3 are identical in terms of their shape, size and microstructure.

In particular, the surface 30 of each cooling fin 3 has a microstructured region 4, which in turn comprises a plurality of indentations 40. The indentations 40 of each cooling fin 3 each extend in a peripheral direction 504 over a complete periphery of the cooling fin 3. FIG. 4 also shows that the microstructured region 4 of each cooling fin 3 formed by the indentations 40 extends over the entire height of the corresponding cooling fin 3.

The indentations 40 of the microstructured region 4 of each cooling fin 3 are formed in such a way that the microstructured region 4 has a corrugated shape. It should be understood that the corrugated shape also defines ridges 41, which together with the indentations 40 form the corrugated shape.

All indentations 40 of a microstructured region 4 have a maximum depth 400 of between 4 μm and 300 μm, preferably between 10 μm and 100 μm. Accordingly, all ridges 41 of a microstructured region 4 have a maximum height 401 of between 4 μm and 300 μm, preferably between 10 μm and 100 μm. The depth 400 of an indentation 40 or the height 401 of a ridge 41 is a dimension parallel to the direction of arrangement 502 of the cooling fins 3 or the flow direction 500 of the cooling medium.

The surface 20 of the main body 2 is not microstructured in this exemplary embodiment. Thus, non-microstructured regions 5 are formed between the cooling fins 3 within the meaning of the present invention.

FIG. 6 refers to a cooling plate 1 according to a third exemplary embodiment of the present invention. The cooling plate 1 according to the third exemplary embodiment can replace the cooling plate 1 in the power electronics assembly 100 shown in FIG. 3.

The cooling plate 1 according to the third exemplary embodiment differs fundamentally from that according to the first exemplary embodiment in that the indentations 40 are not identical. The indentations have different shapes, and their depths also vary in the flow direction 500 of the cooling medium. Furthermore, the indentations 40 have different maximum depths 400.

In particular, the indentations 40 are formed in such a way that an enlargement of the surface area 20 of the main body 2 caused by the indentations 40 increases in the flow direction 500. As can be seen in FIG. 6, the maximum depth 400 of the indentations 40 increases in the flow direction 500 of the cooling medium.

The fact that the cooling medium becomes warmer in the flow direction 500 due to the heat transfer via the cooling plate 1 can be compensated for by the different design of the indentations 40 described above. In an advantageous manner, the indentations 40 are designed in such a way that all power electronics units 201 through 203 of the power electronics 200 advantageously experience the same cooling capacity and in particular also have the same temperature at steady-state losses.

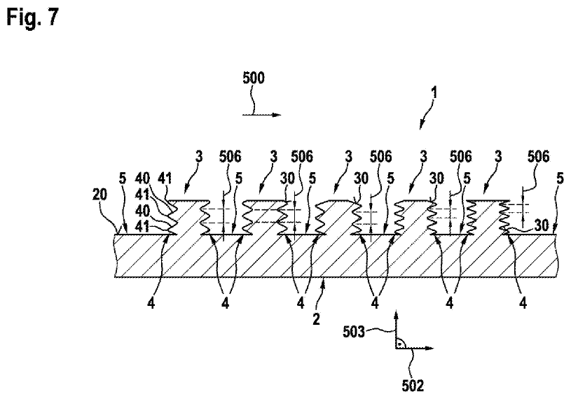

FIG. 7 refers to a cooling plate 1 according to a fourth exemplary embodiment of the present invention. The cooling plate 1 according to the fourth exemplary embodiment can be used in the power electronics assembly 100 of FIG. 3 instead of the cooling plate 1 according to the first exemplary embodiment.

The cooling plate 1 according to the fourth exemplary embodiment differs fundamentally from that according to the second exemplary embodiment in that the microstructuring of the surfaces 30 of the cooling fins 3 is not identical. In particular, the microstructured regions 4 formed by the indentations 40 are not identical.

The microstructured regions 4 of the cooling fins 3 are designed in such a way that an enlargement of the surface area 30 of the cooling fins 3 in the flow direction 500 caused by the microstructured regions 4 increases. In other words, this means that a surface area of the microstructured regions 4 or their area content preferably increases in the flow direction 500.

FIG. 7 shows that a distance 506 from the center of the indentation to the center of the indentation of the microstructured regions 4 of the cooling fins 3 decreases in the flow direction 500. This means that the enlargement of surface area is greater for the last cooling fin 3 in the flow direction 500 than for the first cooling fin 3.

In an advantageous manner, the microstructured regions 40 are designed in such a way that all power electronics units 201 through 203 of the power electronics 200 advantageously experience the same cooling capacity and, in particular, also have the same temperature in the event of steady-state losses.

It should be noted that in the cooling plate 1 of the present invention, both the surface 20 of the main body 2 and the surface 30 of one or more cooling fins 3 can be microstructured. In particular, a cooling plate 1 can be designed as a combination of the cooling plates 1 according to the first and the second exemplary embodiment or as a combination of the cooling plates 1 according to the third and the fourth exemplary embodiment. A cooling plate 1 as a combination of the cooling plate 1 according to the first exemplary embodiment with the cooling plate 1 according to the third exemplary embodiment or as a combination of the cooling plate 1 according to the second exemplary embodiment with the cooling plate 1 according to the fourth exemplary embodiment is also conceivable.

1. A cooling plate (1) of a cooler (10), through which fluid can flow, for cooling power electronics (200), the cooling plate (1) comprising a main body (2) and a plurality of cooling fins (3) which protrude from the main body (2), wherein a surface (20) of the main body (2) and/or a surface (30) of at least one cooling fin (3) has/have at least one defined microstructured region (4).

2. The cooling plate (1) according to claim 1, wherein the microstructured region (4) of the surface (20) of the main body (2) is formed by at least one indentation (40).

3. The cooling plate (1) according to claim 1, wherein the microstructured region (4) of the surface (20) of the main body (2) is formed on a cooling fin (3).

4. The cooling plate (1) according to claim 1, wherein the microstructured region (4) of the surface (20) of the main body (2) is arranged upstream of a cooling fin (3) in a flow direction (500) of a coolant.

5. The cooling plate (1) according to claim 1, wherein a width (505) of the microstructured region (4) of the surface (20) of the main body (2) is equal to a width (300) of a cooling fin (3) with which the microstructured region (4) of the surface (20) of the main body (2) is associated.

6. The cooling plate (1) according to claim 1, wherein the microstructured region (4) of the surface (30) of the at least one cooling fin (3) is formed by at least one indentation (40).

7. The cooling plate (1) according to claim 1, wherein the surface (30) of the at least one cooling fin (3) is a surface of a peripheral area of the cooling fin (3) and wherein the microstructured region (4) of it extends in a peripheral direction (504) over a complete periphery of the cooling fin (3) or a part of the periphery of the cooling fin (3).

8. The cooling plate (1) according to claim 1, wherein the microstructured region (4) of the surface (20) of the main body (2) comprises a plurality of indentations (40) arranged such that the microstructured region (4) has a corrugated shape,
and/or
wherein the microstructured region (4) of the surface (30) of the at least one cooling fin (4) comprises a plurality of indentations (40) arranged such that the microstructured region (4) has a corrugated shape.

9. The cooling plate (1) according to claim 8, wherein a maximum depth (400) of each indentation (40) is between 4 μm and 300 μm.

10. The cooling plate (1) according to claim 1, wherein the cooling plate (1) is designed configured as a pin-fin plate, wherein the cooling fins (3) are pin-shaped.

11. The cooling plate (1) according to claim 1, wherein the microstructured region (4) of the surface (20) of the main body (2) and/or of the surface (30) of the at least one cooling fin (3) is produced by a surface treatment of the corresponding surface (30, 40).

12. The cooling plate (1) according to claim 1,
wherein the surface (20) of the main body (2) has a plurality of defined microstructured regions (4), which are each assigned to a cooling fin (3) and are configured in such a way that an enlargement of the surface area (20) of the main body (2) caused by the microstructured regions (4) increases in a direction of arrangement (502) of the cooling fins (3), wherein the direction of arrangement (502) is parallel to a flow direction (500) of a cooling medium,
and/or
wherein the surface (30) of each cooling fin (3) of the plurality of cooling fins (3) has a defined microstructured region (4), wherein the microstructured regions of the cooling fins (3) are configured such that an enlargement of the surface area (30) of the cooling fins (3) caused by the microstructured regions (4) increases in a direction of arrangement (502) of the cooling fins (3), wherein the direction of arrangement (502) is parallel to a flow direction (500) of a cooling medium.

13. A cooler (10) through which fluid can flow, for cooling power electronics (200), the cooler (10) comprising a cooling plate (1) according to claim 1 and an interior (11) in which the cooling fins (3) of the cooling plate (1) are arranged.

14. A power electronics assembly (100), comprising power electronics (200) and a cooler (10) according to claim 13, wherein the power electronics (200) comprises a plurality of power electronics units (201, 202, 203) which are arranged in succession in a flow direction (500) of a cooling medium, and the at least one defined microstructured region (4) has a plurality of predefined microstructured regions (4) which are configured in such a way that all power electronics units (201, 202, 203) experience a same cooling capacity.

15. The cooling plate (1) according to claim 2, wherein the indentation (40) is preferably formed as a trough.

16. The cooling plate (1) according to claim 3, wherein the microstructured region (4) of the surface (20) of the main body (2) is formed directly on a cooling fin (3).

17. The cooling plate (1) according to claim 7, wherein the microstructured region (4) preferably extends over a complete height of the cooling fin (3) or a part of the height of the cooling fin (3).

18. The cooling plate (1) according to claim 9, wherein the maximum depth (400) of each indentation (40) is between 10 μm and 100 μm.

19. The cooling plate (1) according to claim 11, wherein the surface treatment is provided with a laser.
